(19) United States
(12) Patent Application Publication
(10) Pub. No.: US 2026/0090158 A1
(43) Pub. Date: Mar. 26, 2026

(54) DISPLAY DEVICE AND REPAIR METHOD OF DISPLAY DEVICE

(71) Applicant: AUO Corporation, Hsinchu City (TW)

(72) Inventor: Chia-Chun Chang, Hsinchu City (TW)

(73) Assignee: AUO Corporation, Hsinchu City (TW)

(21) Appl. No.: 18/923,691

(22) Filed: Oct. 23, 2024

(30) Foreign Application Priority Data
Sep. 25, 2024 (TW) 113136465

(51) Int. Cl. H01L 33/62; H01L 25/16

(52) U.S. Cl. CPC H10H 20/857; H10W 90/00; H10H 20/0364

(57) ABSTRACT

A display device includes first, second, and third sub-pixels. The first, second, and third sub-pixels each have a default light-emitting area and a repair area. The first sub-pixel includes a first light-emitting element and a first repair light-emitting element respectively disposed in the default light-emitting area and the repair area. The second sub-pixel includes a second repair light-emitting element disposed in the repair area. The third sub-pixel includes a third light-emitting element disposed in the default light-emitting area. The first light-emitting element, the first repair light-emitting element, the second repair light-emitting element, and the third light-emitting element are light-emitting elements of the same color.

### CROSS-REFERENCE TO RELATED APPLICATION

This application claims the priority benefit of Taiwan application serial no. 113136465, filed on Sep. 25, 2024. The entirety of the above-mentioned patent application is hereby incorporated by reference herein and made a part of this specification.

### BACKGROUND

### Technical Field

The disclosure relates to a display device and a repair method of the display device.

### Description of Related Art

The mass transfer technology aims to transfer a large number of micro light-emitting diodes (μLEDs) from a growth substrate or intermediate substrate to specific locations on a display panel, which is crucial for producing high-resolution displays. Micro light-emitting diodes have advantages such as high brightness, low power consumption, and high contrast ratio, and do not require a backlight source, making them potential candidates as the next-generation display technology.

However, pixels in the display panel may malfunction due to defects in the micro light-emitting diodes themselves or errors in the mass transfer process, which affects the display quality of the panel. How to repair damaged or misaligned micro light-emitting diodes becomes a key issue in solving the above problem in the development of micro light-emitting diode display technology.

### SUMMARY

The disclosure provides a display device and a repair method of the display device, which can repair damaged sub-pixels.

At least one embodiment of the disclosure provides a display device, which includes a first sub-pixel, at least one second sub-pixel, and a third sub-pixel. The first sub-pixel has a first default light-emitting area and a first repair area, and includes a first light-emitting element and a first repair light-emitting element disposed in the first default light-emitting area and the first repair area, respectively. The first light-emitting element and the first repair light-emitting element are connected in parallel. The second sub-pixel has a second default light-emitting area and a second repair area, and includes a second repair light-emitting element disposed in the second repair area. The second default light-emitting area does not have any light-emitting diode disposed therein or has a malfunctioning second light-emitting element. The third sub-pixel has a third default light-emitting area and a third repair area. The second sub-pixel is located between the first sub-pixel and the third sub-pixel in a first direction. The third sub-pixel includes a third light-emitting element disposed in the third default light-emitting area. The third repair area does not have any light-emitting diode disposed therein. The first light-emitting element, the first repair light-emitting element, the second repair light-emitting element, and the third light-emitting element are light-emitting elements of the same color. The first default light-emitting area, the first repair area, the second default light-emitting area, the second repair area, the third default light-emitting area, and the third repair area are arranged along the first direction.

At least one embodiment of the disclosure provides a repair method of a display device, including providing a circuit substrate, and the circuit substrate includes first, second, and third sub-pixel areas. The first sub-pixel area has a first default light-emitting area and a first repair area. The second sub-pixel area has a second default light-emitting area and a second repair area. The third sub-pixel area has a third default light-emitting area and a third repair area. A first light-emitting element, a second light-emitting element, and a third light-emitting element are transferred to the first default light-emitting area, the second default light-emitting area, and the third default light-emitting area, respectively. A test procedure is performed on the first light-emitting element, the second light-emitting element, and the third light-emitting element. The second light-emitting element is malfunctioning, while the first light-emitting element and the third light-emitting element emit light during the test procedure. A first repair light-emitting element and a second repair light-emitting element are transferred to the first repair area and the second repair area, respectively.

### BRIEF DESCRIPTION OF THE DRAWINGS

FIG. 1A to FIG. 1D are top views illustrating a manufacturing method of a display device according to an embodiment of the disclosure.

FIG. 2 is a top view illustrating a display device according to an embodiment of the disclosure.

FIG. 3 is a top view illustrating a display device according to an embodiment of the disclosure.

FIG. 4, FIG. 5, and FIG. 6 are partial top views illustrating different areas of a display device according to an embodiment of the disclosure.

FIG. 7A to FIG. 7D are top views illustrating a manufacturing method of a display device according to an embodiment of the disclosure.

FIG. 8A to FIG. 8B are top views illustrating a manufacturing method of a display device according to an embodiment of the disclosure.

FIG. 9 is a circuit diagram of a sub-pixel according to an embodiment of the disclosure.

### DESCRIPTION OF THE EMBODIMENTS

In this specification, terms such as “first”, “second”, and “third” are used only to distinguish different elements or areas from each other, and are not intended to impose limitations on these elements or areas. Furthermore, terms such as “Type A”, “Type B”, and “Type C” are used only to distinguish the colors corresponding to different elements or areas. For example, one of “Type A”, “Type B”, and “Type C” may represent red, another may represent green, and the last one may represent blue. The terms “first”, “second”, “third”, as well as “Type A”, “Type B”, “Type C” used in this specification may be omitted without departing from the scope of the disclosure. For instance, “first Type A sub-pixel” may also be simply referred to as “first sub-pixel”, “Type A sub-pixel”, or “sub-pixel”.

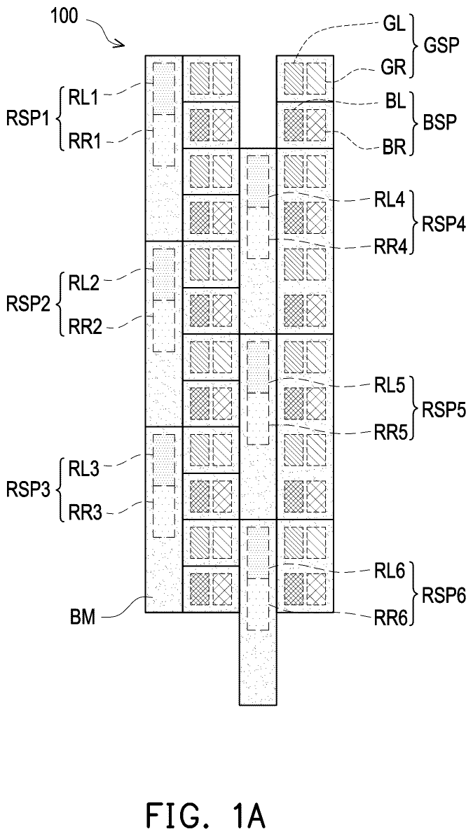

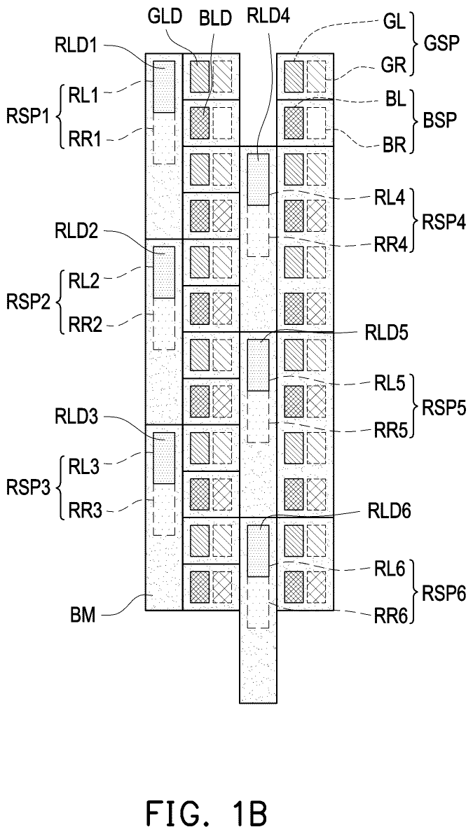

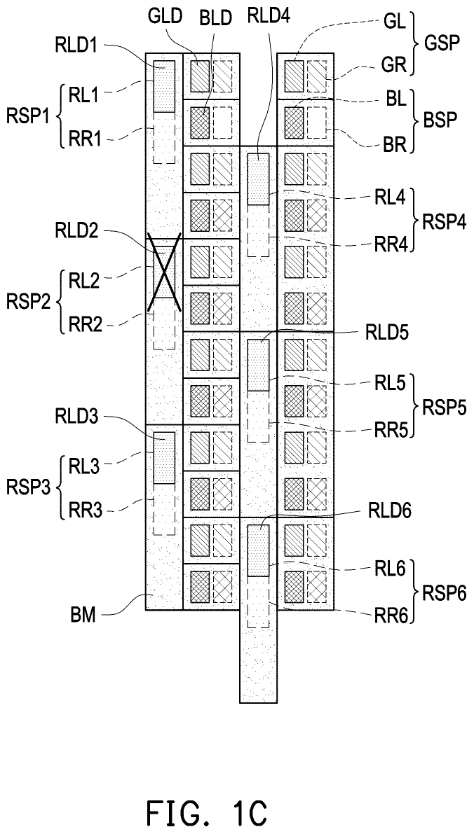

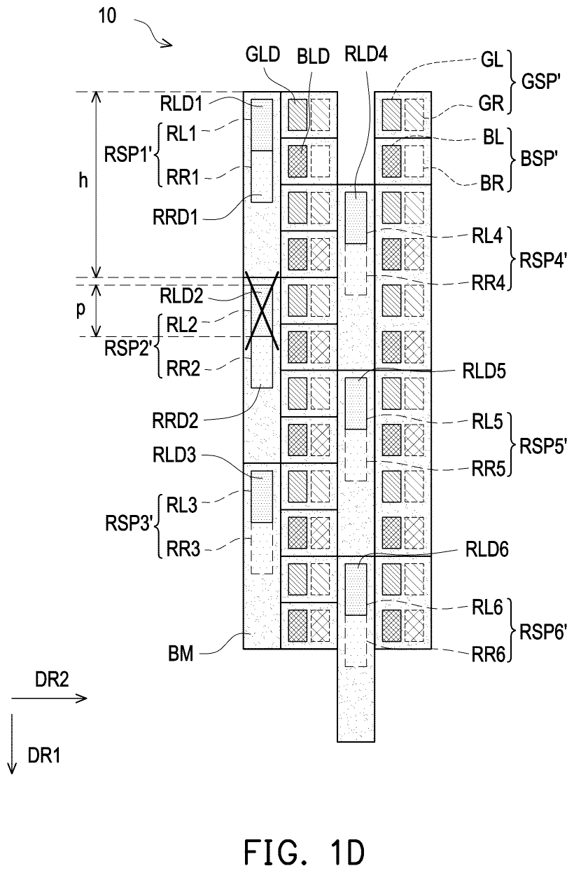

FIG. 1A to FIG. 1D are top views illustrating a manufacturing method of a display device 10 according to an embodiment of the disclosure. Referring to FIG. 1A, a circuit substrate 100 is provided. The circuit substrate 100 includes multiple Type A sub-pixel areas (FIG. 1A shows a first Type A sub-pixel area RSP1, a second Type A sub-pixel area RSP2, a third Type A sub-pixel area RSP3, a fourth Type A sub-pixel area RSP4, a fifth Type A sub-pixel area RSP5, and a sixth Type A sub-pixel area RSP6), multiple Type B sub-pixel areas GSP, and multiple Type C sub-pixel areas BSP. In some embodiments, as viewed from a top view, these sub-pixel areas are separated from each other by a black matrix BM or other light-shielding structures, thereby reducing interference between different sub-pixels.

Each of the Type A sub-pixel areas has a Type A default light-emitting area and a Type A repair area. For example, the first Type A sub-pixel area RSP1 has a first Type A default light-emitting area RL1 and a first Type A repair area RR1; the second Type A sub-pixel area RSP2 has a second Type A default light-emitting area RL2 and a second Type A repair area RR2; the third Type A sub-pixel area RSP3 has a third Type A default light-emitting area RL3 and a third Type A repair area RR3; the fourth Type A sub-pixel area RSP4 has a fourth Type A default light-emitting area RL4 and a fourth Type A repair area RR4; the fifth Type A sub-pixel area RSP5 has a fifth Type A default light-emitting area RL5 and a fifth Type A repair area RR5; and the sixth Type A sub-pixel area RSP6 has a sixth Type A default light-emitting area RL6 and a sixth Type A repair area RR6.

Each of the Type B sub-pixel areas GSP has a Type B default light-emitting area GL and a Type B repair area GR. Each of the Type C sub-pixel areas BSP has a Type C default light-emitting area BL and a Type C repair area BR.

In some embodiments, each sub-pixel area of the circuit substrate 100 corresponds to a sub-pixel driving circuit, and each sub-pixel driving circuit includes one or more thin film transistors (T) and one or more capacitors (C). For example, the sub-pixel driving circuit may have a 1T1C architecture, a 2T1C architecture, a 3T1C architecture, a 3T2C architecture, a 4T1C architecture, a 4T2C architecture, a 5T1C architecture, a 5T2C architecture, a 6T1C architecture, a 6T2C architecture, a 7T2C architecture, or any other possible architecture. The light-emitting elements on the sub-pixel area are driven to emit light by such a driving circuit.

Referring to FIG. 1B, multiple Type A light-emitting elements (FIG. 1B illustrates a first Type A light-emitting element RLD1, a second Type A light-emitting element RLD2, a third Type A light-emitting element RLD3, a fourth Type A light-emitting element RLD4, a fifth Type A light-emitting element RLD5, and a sixth Type A light-emitting element RLD6), multiple Type B light-emitting elements GLD, and multiple Type C light-emitting elements BLD are transferred onto the circuit substrate 100 through one or more mass transfer processes, and are disposed in corresponding default light-emitting areas, respectively. In FIG. 1A and FIG. 1B, areas provided with no light-emitting elements are shown in dashed outlines, and areas provided with light-emitting elements are shown in solid outlines.

The Type A light-emitting elements, the Type B light-emitting elements GLD, and the Type C light-emitting elements BLD are light-emitting diodes of different colors. In some embodiments, the Type A light-emitting elements, the Type B light-emitting elements GLD, and the Type C light-emitting elements BLD are red light-emitting diodes, green light-emitting diodes, and blue light-emitting diodes, respectively, but the disclosure is not limited thereto. In other embodiments, the Type A light-emitting elements may be green light-emitting diodes or blue light-emitting diodes, the Type B light-emitting elements GLD may be red light-emitting diodes or blue light-emitting diodes, and the Type C light-emitting elements BLD may be red light-emitting diodes or green light-emitting diodes.

In this embodiment, the first Type A light-emitting element RLD1, the second Type A light-emitting element RLD2, the third Type A light-emitting element RLD3, the fourth Type A light-emitting element RLD4, the fifth Type A light-emitting element RLD5, and the sixth Type A light-emitting element RLD6 are transferred onto the first Type A default light-emitting area RL1, the second Type A default light-emitting area RL2, the third Type A default light-emitting area RL3, the fourth Type A default light-emitting area RL4, the fifth Type A default light-emitting area RL5, and the sixth Type A default light-emitting area RL6, respectively. The type B light-emitting elements GLD are transferred onto the Type B default light-emitting areas GL, and the Type C light-emitting elements BLD are transferred onto the Type C default light-emitting areas BL, respectively.

These light-emitting elements are bonded to the circuit substrate 100 using solder, conductive adhesive, or other materials, thereby enabling the sub-pixel driving circuits within the circuit substrate 100 to drive these light-emitting elements. However, some of the light-emitting elements may malfunction due to defects thereof or misalignment during the transfer process. A repair process for the Type A light-emitting elements will be described below.

Referring to FIG. 1C, a test procedure is performed on the first Type A light-emitting element RLD1, the second Type A light-emitting element RLD2, the third Type A light-emitting element RLD3, the fourth Type A light-emitting element RLD4, the fifth Type A light-emitting element RLD5, and the sixth Type A light-emitting element RLD6. Through the test procedure, it is determined that the second Type A light-emitting element RLD2 is a malfunctioning light-emitting element, while the first Type A light-emitting element RLD1, the third Type A light-emitting element RLD3, the fourth Type A light-emitting element RLD4, the fifth Type A light-emitting element RLD5, and the sixth Type A light-emitting element RLD6 emit light during the test procedure (for example, these light-emitting elements normally emit light at expected wavelength and expected brightness).

In FIG. 1C, the malfunctioning light-emitting element is marked with a cross. Although in FIG. 1C to FIG. 1D, the malfunctioning second Type A light-emitting element RLD2 is placed on the second Type A default light-emitting area RL2, the disclosure is not limited thereto. In practice, due to misalignment in the transfer process, there may be no light-emitting element (that is, light-emitting diode) in the second Type A default light-emitting area RL2.

Referring to FIG. 1D, the first Type A repair light-emitting element RRD1 and the second Type A repair light-emitting element RRD2 are transferred onto the first Type A repair area RR1 and the second Type A repair area RR2, respectively, thereby completing the repair of the Type A light-emitting elements.

In this embodiment, the display device 10 includes multiple Type A sub-pixels (FIG. 1D illustrates a first Type A sub-pixel RSP1′, a second Type A sub-pixel RSP2′, a third Type A sub-pixel RSP3′, a fourth Type A sub-pixel RSP4′, a fifth Type A sub-pixel RSP5′, and a sixth Type A sub-pixel RSP6′), multiple Type B sub-pixels GSP′, and multiple Type C sub-pixels BSP′.

The first Type A sub-pixel RSP1′ has a first Type A default light-emitting area RL1 and a first Type A repair area RR1, and includes a first Type A light-emitting element RLD1 and a first Type A repair light-emitting element RRD1 disposed in the first Type A default light-emitting area RL1 and the first Type A repair area RR1, respectively. The first Type A light-emitting element RLD1 and the first Type A repair light-emitting element RRD1 are connected in parallel. Specifically, the anode of the first Type A light-emitting element RLD1 is electrically connected to the anode of the first Type A repair light-emitting element RRD1, and the cathode of the first Type A light-emitting element RLD1 is electrically connected to the cathode of the first Type A repair light-emitting element RRD1. Therefore, the first Type A light-emitting element RLD1 and the first Type A repair light-emitting element RRD1 turn on and turn off simultaneously.

The second Type A sub-pixel RSP2′ has a second Type A default light-emitting area RL2 and a second Type A repair area RR2, and includes a second Type A repair light-emitting element RRD2 disposed in the second Type A repair area RR2. The second Type A default light-emitting area RL2 does not have any light-emitting diode disposed therein or has the malfunctioning second Type A light-emitting element RLD2.

In this embodiment, the distance between the second Type A repair light-emitting element RRD2 and the first Type A light-emitting element RLD1 is approximately equal to the length h of the sub-pixel in the first direction DR1 plus the length p of the second Type A default light-emitting area RL2 or the second Type A repair area RR2 in the first direction DR1. Since the second Type A default light-emitting area RL2 does not include a light-emitting element that normally emits light therein, to prevent the excessive distance between the second Type A repair light-emitting element RRD2 and the first Type A light-emitting element RLD1 from forming a dark spot, the first Type A repair light-emitting element RRD1 is still disposed in the first Type A repair area RR1 despite that the first Type A light-emitting element RLD1 may operate normally. The distance between the second Type A repair light-emitting element RRD2 adjacent to the first Type A sub-pixel RSP1′ and the first Type A repair light-emitting element RRD1 of the first Type A sub-pixel RSP1′ is substantially equal to the length h of the first Type A sub-pixel RSP1′ in the first direction DR1.

The third Type A sub-pixel RSP3′ has a third Type A default light-emitting area RL3 and a third Type A repair area RR3. The third Type A sub-pixel RSP3′ includes a third Type A light-emitting element RLD3 disposed in the third Type A default light-emitting area RL3. The fourth Type A sub-pixel RSP4′ has a fourth Type A default light-emitting area RL4 and a fourth Type A repair area RR4. The fourth Type A sub-pixel RSP4′ includes a fourth Type A light-emitting element RLD4 disposed in the fourth Type A default light-emitting area RL4. The fifth Type A sub-pixel RSP5′ has a fifth Type A default light-emitting area RL5 and a fifth Type A repair area RR5. The fifth Type A sub-pixel RSP5′ includes a fifth Type A light-emitting element RLD5 disposed in the fifth Type A default light-emitting area RL5. The sixth Type A sub-pixel RSP6′ has a sixth Type A default light-emitting area RL6 and a sixth Type A repair area RR6. The sixth Type A sub-pixel RSP6′ includes a sixth Type A light-emitting element RLD6 disposed in the sixth Type A default light-emitting area RL6. In some embodiments, the third Type A repair area RR3 to the sixth Type A repair area RR6 do not have any light-emitting diode disposed therein.

The second Type A sub-pixel RSP2′ is located between the first Type A sub-pixel RSP1′ and the third Type A sub-pixel RSP3′ in the first direction DR1. In this embodiment, one second Type A sub-pixel RSP2′ is located between the first Type A sub-pixel RSP1′ and the third Type A sub-pixel RSP3′, but the disclosure is not limited thereto. In other embodiments, two or more second Type A sub-pixels RSP2′ may be located between the first Type A sub-pixel RSP1′ and the third Type A sub-pixel RSP3′.

The first Type A default light-emitting area RL1, the first Type A repair area RR1, the second Type A default light-emitting area RL2, the second Type A repair area RR2, the third Type A default light-emitting area RL3, and the third Type A repair area RR3 are arranged sequentially along the first direction DR1, for example, aligned in a row along the first direction DR1. The fourth Type A default light-emitting area RL4, the fourth Type A repair area RR4, the fifth Type A default light-emitting area RL5, the fifth Type A repair area RR5, the sixth Type A default light-emitting area RL6, and the sixth Type A repair area RR6 are arranged sequentially along the first direction DR1, for example, aligned in another row along the first direction DR1.

In some embodiments, the fourth Type A light-emitting element RLD4, the fifth Type A light-emitting element RLD5, and the sixth Type A light-emitting element RLD6 are arranged in a staggered manner along the second direction DR2 with the first Type A light-emitting element RLD1, the second Type A light-emitting element RLD2, and the third Type A light-emitting element RLD3, thereby avoiding the problem of uneven brightness in the displayed image. The second direction DR2 is not parallel to the first direction DR1. For example, the second direction DR2 is perpendicular to the first direction DR1.

The first Type A light-emitting element RLD1, the first Type A repair light-emitting element RRD1, the second Type A repair light-emitting element RRD2, the third Type A light-emitting element RLD3, the fourth Type A light-emitting element RLD4, the fifth Type A light-emitting element RLD5, and the sixth Type A light-emitting element RLD6 are light-emitting elements of the same color.

The first Type A light-emitting element RLD1, the third Type A light-emitting element RLD3, the fourth Type A light-emitting element RLD4, the fifth Type A light-emitting element RLD5, and the sixth Type A light-emitting element RLD6 have substantially the same light-emitting efficiency. The light-emitting efficiency of the first Type A repair light-emitting element RRD1 and the light-emitting efficiency of the second Type A repair light-emitting element RRD2 may be the same as or different from the light-emitting efficiency of the first Type A light-emitting element RLD1, the third Type A light-emitting element RLD3, the fourth Type A light-emitting element RLD4, the fifth Type A light-emitting element RLD5, and the sixth Type A light-emitting element RLD6. For example, the light-emitting efficiency of the first Type A repair light-emitting element RRD1 is lower than the light-emitting efficiency of the first Type A light-emitting element RLD1, so that the brightness of the light emitted by the first Type A repair light-emitting element RRD1 is lower than the brightness of the light emitted by the first Type A light-emitting element RLD1. In some embodiments, the light-emitting efficiency of the second Type A repair light-emitting element RRD2 is also lower than the light-emitting efficiency of the first Type A light-emitting element RLD1. In some embodiments, the light-emitting efficiency of the first Type A repair light-emitting element RRD1 is lower than or equal to the light-emitting efficiency of the second Type A repair light-emitting element RRD2. In some embodiments, in addition to using repair light-emitting elements with lower light-emitting efficiency, the quality of the displayed image may be further improved through digital compensation. By using repair light-emitting elements with lower light-emitting efficiency, the magnitude of digital compensation may be relatively small. A method of digital compensation will be described later.

In some embodiments, the first Type A sub-pixel RSP1′ includes two light-emitting elements that can emit light (that is, the first Type A light-emitting element RLD1 and the first Type A repair light-emitting element RRD1). To prevent a bright spot from being formed in the first Type A sub-pixel RSP1′, the first Type A repair light-emitting element RRD1 with lower light-emitting efficiency is disposed in the first Type A sub-pixel RSP1′. On the other hand, since the distance between the second Type A repair light-emitting element RRD2 and the third Type A light-emitting element RLD3 is relatively small (approximately equal to the length h of the sub-pixel in the first direction DR1 minus the length p), to prevent a bright spot from being formed between the second Type A sub-pixel RSP2′ and the third Type A sub-pixel RSP3′, the second Type A repair light-emitting element RRD2 with lower light-emitting efficiency is disposed in the second Type A sub-pixel RSP2′.

In some embodiments, the light-emitting efficiency of the first Type A light-emitting element RLD1, the third Type A light-emitting element RLD3, the fourth Type A light-emitting element RLD4, the fifth Type A light-emitting element RLD5, and the sixth Type A light-emitting element RLD6 is substantially equal to the light-emitting efficiency of the first Type A repair light-emitting element RRD1 and the second Type A repair light-emitting element RRD2. Then, when the display device 10 displays an image, the maximum brightness of each of the first Type A light-emitting element RLD1, the first Type A repair light-emitting element RRD1, and the second Type A repair light-emitting element RRD2 is reduced through digital compensation. For example, the data driving circuit provides a data voltage to each sub-pixel through a data line. A compensation circuit is coupled to the data driving circuit, and the compensation circuit is configured to further provide a digital compensation value based on the level of the data voltage to be output by the data driving circuit. For example, the compensation circuit is configured to calculate the digital compensation values for the data voltages provided to different sub-pixels according to the grayscale value conversion requirements of different sub-pixels. Based on the digital compensation values calculated by the compensation circuit, the data driving circuit may generate digitally compensated data voltages (which may be higher or lower than the standard data voltage).

In some embodiments, the above digital compensation value for the data voltage is calculated by the compensation circuit through table lookup in a digital compensation table. For example, Table 1 is a digital compensation table for the Type A sub-pixels in FIG. 1D, and the digital compensation value for each Type A sub-pixel in FIG. 1D is shown in the corresponding position in Table 1.

TABLE 1

| | |
|---|---|
| 0.6 | 1 |
| 0.8 | 1 |
| 1 | 1 |

Referring to Table 1 and FIG. 1D, the digital compensation value (for example, 0.6) of the first Type A sub-pixel RSP1′ is lower than the digital compensation value (for example, 0.8) of the second Type A sub-pixel RSP2′, while the digital compensation value of the second Type A sub-pixel RSP2′ is lower than the digital compensation values (for example, 1) of the third Type A sub-pixel RSP3′, the fourth Type A sub-pixel RSP4′, the fifth Type A sub-pixel RSP5′, and the sixth Type A sub-pixel RSP6′. The larger the digital compensation value, the higher the maximum brightness of the corresponding light-emitting element when the display device 10 displays an image. Reducing the digital compensation value of the first Type A sub-pixel RSP1′ can prevent a bright spot from being formed in the first Type A sub-pixel RSP1′. Reducing the digital compensation value of the second Type A sub-pixel RSP2′ can prevent a bright spot from being formed between the second Type A sub-pixel RSP2′ and the third Type A sub-pixel RSP3′.

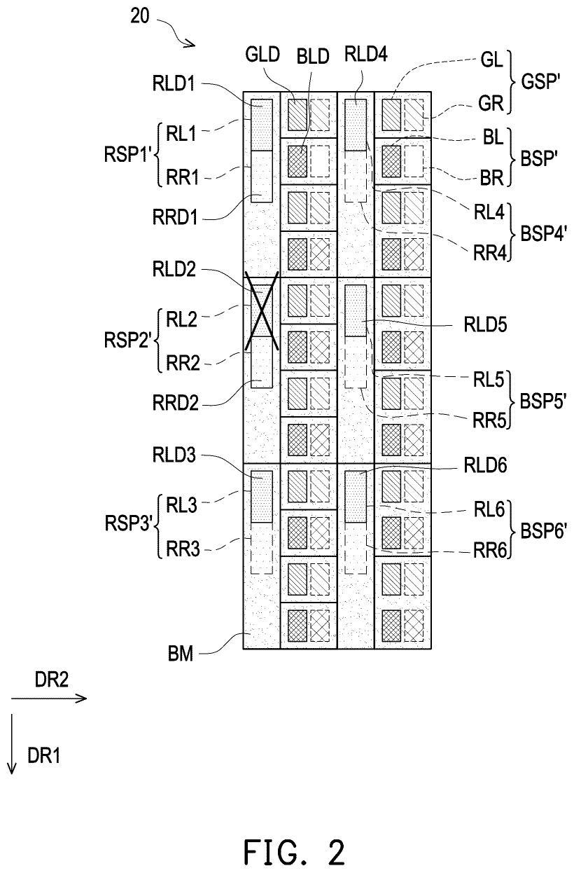

FIG. 2 is a top view illustrating a display device 20 according to an embodiment of the disclosure. It should be noted that the embodiment of FIG. 2 uses the reference numerals and some contents from the embodiment of FIG. 1A to FIG. 1D, wherein identical or similar reference numerals are used to represent identical or similar elements, and description of identical technical content is omitted. Please refer to the above embodiment for the omitted content, which will not be repeated here.

The difference between the display device 20 in FIG. 2 and the display device 10 in FIG. 1A to FIG. 1D lies in the following. In the display device 10, the first Type A sub-pixel RSP1′, the second Type A sub-pixel RSP2′, and the third Type A sub-pixel RSP3′ are arranged in a staggered manner along the second direction DR2 with the fourth Type A sub-pixel RSP4′, the fifth Type A sub-pixel RSP5′, and the sixth Type A sub-pixel RSP6′. However, in the display device 20, the first Type A sub-pixel RSP1′, the second Type A sub-pixel RSP2′, and the third Type A sub-pixel RSP3′ are aligned along the second direction DR2 with the fourth Type A sub-pixel RSP4′, the fifth Type A sub-pixel RSP5′, and the sixth Type A sub-pixel RSP6′.

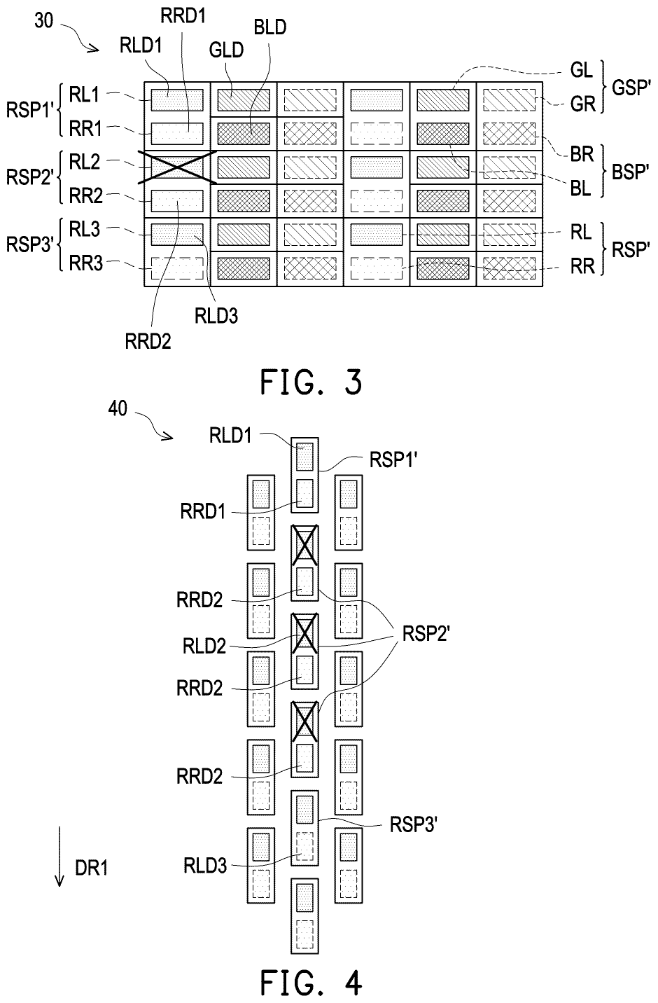

FIG. 3 is a top view illustrating a display device 30 according to an embodiment of the disclosure. It should be noted that the embodiment of FIG. 3 uses the reference numerals and some contents from the embodiment of FIG. 1A to FIG. 1D, wherein identical or similar reference numerals are used to represent identical or similar elements, and description of identical technical content is omitted. Please refer to the above embodiment for the omitted content, which will not be repeated here.

The difference between the display device 30 in FIG. 3 and the display device 10 in FIG. 1A to FIG. 1D lies in the following. In the display device 10, two pixels share one Type A sub-pixel RSP′, or it can be said that one Type B sub-pixel GSP′, one Type C sub-pixel BSP′, and half of a Type A sub-pixel constitute one pixel. However, in the display device 30, one Type B sub-pixel GSP′, one Type C sub-pixel BSP′, and one Type A sub-pixel RSP′ constitute one pixel.

The Type A sub-pixel RSP′ has a Type A repair area RR and a Type A default light-emitting area RL, wherein the Type A light-emitting element RLD is disposed in the corresponding Type A default light-emitting area RL. In FIG. 3, three of the Type A sub-pixels RSP′ are labeled as the first Type A sub-pixel RSP1′, the second Type A sub-pixel RSP2′, and the third Type A sub-pixel RSP3′, while three of the Type A light-emitting elements RLD are labeled as the first Type A light-emitting element RLD1, the second Type A light-emitting element RLD2, and the third Type A light-emitting element RLD3. The first Type A sub-pixel RSP1′ and the second Type A sub-pixel RSP2′ include the first Type A repair light-emitting element RRD1 and the second Type A repair light-emitting element RRD2, respectively. The second Type A sub-pixel RSP2′ may optionally include a malfunctioning second Type A light-emitting element RLD2.

FIG. 4, FIG. 5, and FIG. 6 are partial top views illustrating different areas of a display device 40 according to an embodiment of the disclosure. To facilitate the explanation of a method for repairing Type A sub-pixels, FIG. 4, FIG. 5, and FIG. 6 show only the Type A sub-pixels in the display device, and omit the Type B sub-pixels and Type C sub-pixels.

Referring to FIG. 4, two or more repaired second Type A sub-pixels RSP2′ are located between the first Type A sub-pixel RSP1′ and the third Type A sub-pixel RSP3′. The first Type A sub-pixel RSP1′ includes a first Type A light-emitting element RLD1 and a first Type A repair light-emitting element RRD1. The second Type A sub-pixel RSP2′ includes a second Type A repair light-emitting element RRD2, and may optionally include a malfunctioning second Type A light-emitting element RLD2. The third Type A sub-pixel RSP3′ includes a third Type A light-emitting element RLD3.

In some embodiments, the light-emitting efficiency of the first Type A light-emitting element RLD1 and the third Type A light-emitting element RLD3 is substantially equal to the light-emitting efficiency of the first Type A repair light-emitting element RRD1 and the second Type A repair light-emitting element RRD2. When the display device 40 displays an image, the maximum brightness of each of the first Type A light-emitting element RLD1, the first Type A repair light-emitting element RRD1, and the second Type A repair light-emitting element RRD2 closest to the third Type A sub-pixel RSP3′ in the first direction DR1 is reduced through digital compensation.

For example, Table 2 is a digital compensation table for the Type A sub-pixels in FIG. 4, and the digital compensation value for each Type A sub-pixel in FIG. 4 is shown in the corresponding position in Table 2.

TABLE 2

| | | |
|---|---|---|
| 1 | 0.6 | 1 |
| 1 | 1 | 1 |
| 1 | 1 | 1 |
| 1 | 0.8 | 1 |
| 1 | 1 | 1 |
| | 1 | |

Referring to Table 2 and FIG. 4, the digital compensation value (for example, 0.6) of the first Type A sub-pixel RSP1′ is lower than the digital compensation value (for example, 0.8) of the second Type A sub-pixel RSP2′ closest to the third Type A sub-pixel RSP3′ in the first direction DR1, while the digital compensation value of the second Type A sub-pixel RSP2′ closest to the third Type A sub-pixel RSP3′ in the first direction DR1 is lower than the digital compensation values (for example, 1) of the third Type A sub-pixel RSP3′ and other second Type A sub-pixels RSP2′. Reducing the digital compensation value of the first Type A sub-pixel RSP1′ can prevent a bright spot from being formed in the first Type A sub-pixel RSP1′. Reducing the digital compensation value of the second Type A sub-pixel RSP2′ closest to the third Type A sub-pixel RSP3′ in the first direction DR1 can prevent a bright spot from being formed between the second Type A sub-pixel RSP2′ closest to the third Type A sub-pixel RSP3′ in the first direction DR1 and the third Type A sub-pixel RSP3′.

Table 3 and Table 4 are digital compensation tables for the Type A sub-pixels in FIG. 5 and FIG. 6, respectively. The digital compensation value for each Type A sub-pixel in FIG. 5 is shown in the corresponding position in Table 3, and the digital compensation value for each Type A sub-pixel in FIG. 6 is shown in the corresponding position in Table 4.

TABLE 3

| | | | | | | |
|---|---|---|---|---|---|---|
| 1 | 0.6 | 1 | 0.6 | 1 | 0.6 | 1 |
| 1 | 0.8 | 1 | 0.8 | 1 | 0.8 | 1 |
| | 1 | | 1 | | 1 | |

TABLE 4

| | | | | |
|---|---|---|---|---|
| 1 | 0.6 | 0.6 | 0.6 | 1 |
| 1 | 1 | 0.8 | 1 | 1 |
| 1 | 0.8 | 1 | 0.8 | 1 |
| | 1 | | 1 | |

Referring to Table 3, Table 4, FIG. 5, and FIG. 6, the digital compensation value (for example, 0.6) of the first Type A sub-pixel RSP1′ and the digital compensation value (for example, 0.8) of the second Type A sub-pixel RSP2′ close to the third Type A sub-pixel RSP3′ in the first direction DR1 are reduced. Therefore, the problem of formation of a bright spot in the first Type A sub-pixel RSP1′ and the problem of formation of a bright spot between the second Type A sub-pixel RSP2′ close to the third Type A sub-pixel RSP3′ in the first direction DR1 and the third Type A sub-pixel RSP3′ can be suppressed.

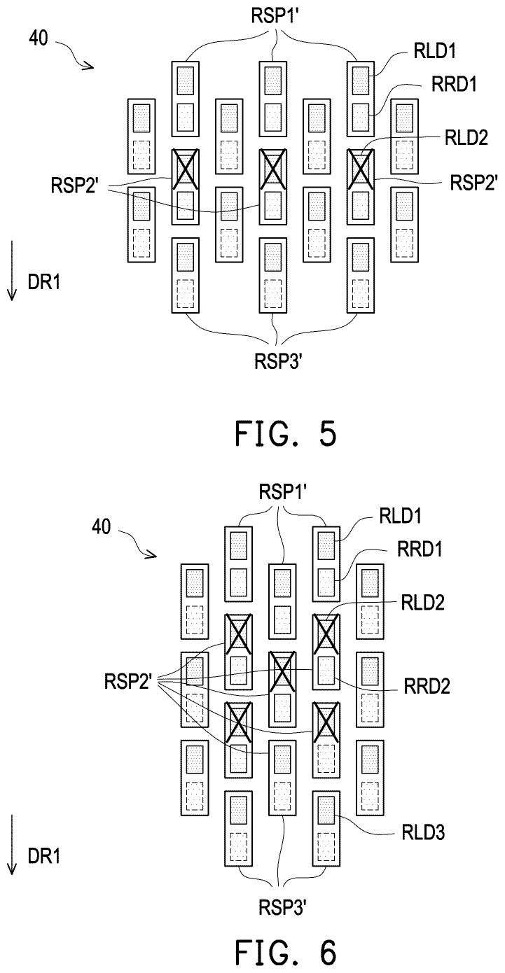

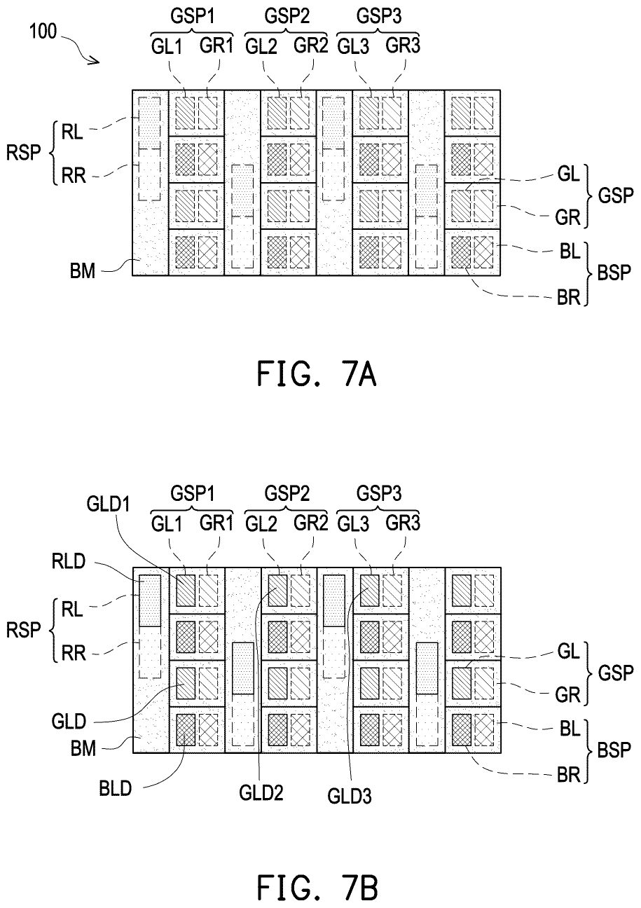

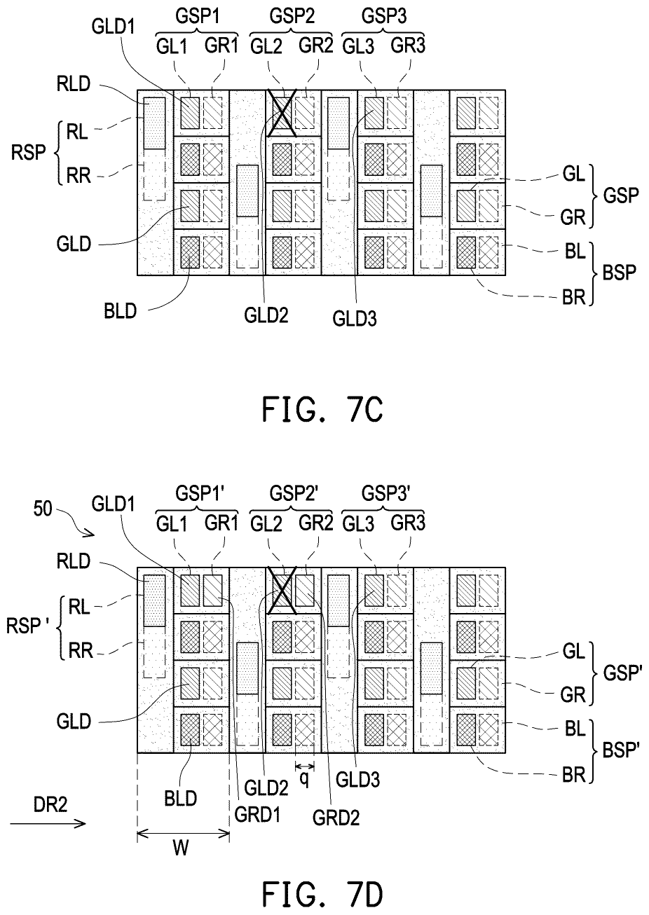

FIG. 7A to FIG. 7D are top views illustrating a manufacturing method of a display device 50 according to an embodiment of the disclosure. It should be noted that the embodiment of FIG. 7A to FIG. 7D uses the reference numerals and some contents from the embodiment of FIG. 1A to FIG. 1D, wherein identical or similar reference numerals are used to represent identical or similar elements, and description of identical technical content is omitted. Please refer to the above embodiment for the omitted content, which will not be repeated here.

FIG. 1A to FIG. 1D illustrate the repair process for Type A light-emitting elements. FIG. 7A to FIG. 7D illustrate the repair process for Type B light-emitting elements. Referring to FIG. 7A, the circuit substrate 100 includes multiple Type A sub-pixel areas RSP, multiple Type B sub-pixel areas GSP, and multiple Type C sub-pixel areas BSP. To facilitate the explanation of the repair process for the Type B sub-pixel areas GSP, three of the Type B sub-pixel areas GSP are marked as a first Type B sub-pixel area GSP1, a second Type B sub-pixel area GSP2, and a third Type B sub-pixel area GSP3.

Each of the Type A sub-pixel areas RSP has a Type A default light-emitting area RL and a Type A repair area RR.

Each of the Type B sub-pixel areas GSP has a Type B default light-emitting area GL and a Type B repair area GR. For example, the first Type B sub-pixel area GSP1 has a first Type B default light-emitting area GL1 and a first Type B repair area GR1; the second Type B sub-pixel area GSP2 has a second Type B default light-emitting area GL2 and a second Type B repair area GR2; and the third Type B sub-pixel area GSP3 has a third Type B default light-emitting area GL3 and a third Type B repair area GR3.

Each of the Type C sub-pixel areas BSP has a Type C default light-emitting area BL and a Type C repair area BR.

Referring to FIG. 7B, multiple Type A light-emitting elements, multiple Type B light-emitting elements GLD (including a first Type B light-emitting element GLD1, a second Type B light-emitting element GLD2, and a third Type B light-emitting element GLD3), and multiple Type C light-emitting elements BLD are transferred onto the circuit substrate 100 through one or more mass transfer processes, and are disposed in corresponding default light-emitting areas, respectively.

The Type A light-emitting elements RLD are transferred onto the Type A default light-emitting areas RL, respectively. The Type B light-emitting elements GLD are transferred onto the Type B default light-emitting areas GL, respectively, wherein the first Type B light-emitting element GLD1, the second Type B light-emitting element GLD2, and the third Type B light-emitting element GLD3 are transferred onto the first Type B default light-emitting area GL1, the second Type B default light-emitting area GL2, and the third Type B default light-emitting area GL3, respectively. The Type C light-emitting elements BLD are transferred onto the Type C default light-emitting areas BL, respectively.

Referring to FIG. 7C, a test procedure is performed on the Type B light-emitting elements GLD. Through the test procedure, it is determined that the second Type B light-emitting element GLD2 is a malfunctioning light-emitting element, while other Type B light-emitting elements GLD (including the first Type B light-emitting element GLD1 and the third Type B light-emitting element GLD3) emit light during the test procedure (for example, these light-emitting elements normally emit light at expected wavelength and expected brightness).

In FIG. 7C, the malfunctioning light-emitting element is marked with a cross. Although in FIG. 7A to FIG. 7D, the malfunctioning second Type B light-emitting element GLD2 is placed on the second Type B default light-emitting area GL2, the disclosure is not limited thereto. In practice, due to misalignment in the transfer process, there may be no light-emitting element (that is, light-emitting diode) in the second Type B default light-emitting area GL2.

Referring to FIG. 7D, the first Type B repair light-emitting element GRD1 and the second Type B repair light-emitting element GRD2 are transferred onto the first Type B repair area GR1 and the second Type B repair area GR2, respectively, thereby completing the repair of the Type B light-emitting elements.

In this embodiment, the display device 50 includes multiple Type A sub-pixels RSP′, multiple Type B sub-pixels GSP′ (including a first Type B sub-pixel GSP1′, a second Type B sub-pixel GSP2′, and a third Type B sub-pixel GSP3′), and multiple Type C sub-pixels BSP′.

The first Type B sub-pixel GSP1′ has a first Type B default light-emitting area GL1 and a first Type B repair area GR1, and includes a first Type B light-emitting element GLD1 and a first Type B repair light-emitting element GRD1 disposed in the first Type B default light-emitting area GL1 and the first Type B repair area GR1, respectively. The first Type B light-emitting element GLD1 and the first Type B repair light-emitting element GRD1 are connected in parallel. Specifically, the anode of the first Type B light-emitting element GLD1 is electrically connected to the anode of the first Type B repair light-emitting element GRD1, and the cathode of the first Type B light-emitting element GLD1 is electrically connected to the cathode of the first Type B repair light-emitting element GRD1. Therefore, the first Type B light-emitting element GLD1 and the first Type B repair light-emitting element GRD1 turn on and turn off simultaneously.

The second Type B sub-pixel GSP2′ has a second Type B default light-emitting area GL2 and a second Type B repair area GR2, and includes a second Type B repair light-emitting element GRD2 disposed in the second Type B repair area GR2. The second Type B default light-emitting area GL2 does not have any light-emitting diode disposed therein or has the malfunctioning second Type B light-emitting element GLD2.

In this embodiment, the distance between the second Type B repair light-emitting element GRD2 and the first Type B light-emitting element GLD1 is approximately equal to the length w of the pixel in the second direction DR2 (including the length of the Type A sub-pixels and the Type B sub-pixels in the second direction DR2) plus the length q of the second Type B default light-emitting area GL2 or the second Type B repair area GR2 in the second direction DR2. Since the second Type B default light-emitting area GL2 does not include a light-emitting element that normally emits light therein, to prevent the excessive distance between the second Type B repair light-emitting element GRD2 and the first Type B light-emitting element GLD1 from forming a dark spot, the first Type B repair light-emitting element GRD1 is still disposed in the first Type B repair area GR1 despite that the first Type B light-emitting element GLD1 may operate normally. The distance between the second Type B repair light-emitting element GRD2 adjacent to the first Type B sub-pixel GSP1′ and the first Type B repair light-emitting element GRD1 of the first Type B sub-pixel GSP1′ is substantially equal to the length w of the pixel in the second direction DR2.

The third Type B sub-pixel GSP3′ has a third Type B default light-emitting area GL3 and a third Type B repair area GR3. The third Type B sub-pixel GSP3′ includes a third Type B light-emitting element GLD3 disposed in the third Type B default light-emitting area GL3. The third Type B repair area GR3 does not have any light-emitting diode disposed therein.

The second Type B sub-pixel GSP2′ is located between the first Type B sub-pixel GSP1′ and the third Type B sub-pixel GSP3′ in the second direction DR2. In this embodiment, one second Type B sub-pixel GSP2′ is located between the first Type B sub-pixel GSP1′ and the third Type B sub-pixel GSP3′, but the disclosure is not limited thereto. In other embodiments, two or more second Type B sub-pixels GSP2′ may be located between the first Type B sub-pixel GSP1′ and the third Type B sub-pixel GSP3′.

The first Type B default light-emitting area GL1, the first Type B repair area GR1, the second Type B default light-emitting area GL2, the second Type B repair area GR2, the third Type B default light-emitting area GL3, and the third Type B repair area GR3 are arranged along the second direction DR2, for example, aligned in a row along the second direction DR2.

The first Type B light-emitting element GLD1, the first Type B repair light-emitting element GRD1, the second Type B repair light-emitting element GRD2, and the third Type B light-emitting element GLD3 are light-emitting elements of the same color.

The first Type B light-emitting element GLD1 and the third Type B light-emitting element GLD3 have substantially the same light-emitting efficiency. In some embodiments, the light-emitting efficiency of the first Type B repair light-emitting element GRD1 and the light-emitting efficiency of the second Type B repair light-emitting element GRD2 may be the same as or different from the light-emitting efficiency of the first Type B light-emitting element GLD1 and the third Type B light-emitting element GLD3. For example, the light-emitting efficiency of the first Type B repair light-emitting element GRD1 is lower than the light-emitting efficiency of the first Type B light-emitting element GLD1, so that the brightness of the light emitted by the first Type B repair light-emitting element GRD1 is lower than the brightness of the light emitted by the first Type B light-emitting element GLD1. In some embodiments, the light-emitting efficiency of the second Type B repair light-emitting element GRD2 is also lower than the light-emitting efficiency of the first Type B light-emitting element GLD1. In some embodiments, the light-emitting efficiency of the first Type B repair light-emitting element GRD1 is lower than or equal to the light-emitting efficiency of the second Type B repair light-emitting element GRD2. In some embodiments, in addition to using repair light-emitting elements with lower light-emitting efficiency, the quality of the displayed image may be further improved through digital compensation. By using repair light-emitting elements with lower light-emitting efficiency, the magnitude of digital compensation may be relatively small.

In some embodiments, disposing the first Type B repair light-emitting element GRD1 with lower light-emitting efficiency in the first Type B sub-pixel GSP1′ can prevent a bright spot from being formed in the first Type A sub-pixel RSP1′. On the other hand, disposing the second Type B repair light-emitting element GRD2 with lower light-emitting efficiency in the second Type B sub-pixel GSP2′ can prevent a bright spot from being formed between the second Type B sub-pixel GSP2′ and the third Type B sub-pixel GSP3′.

In some embodiments, the light-emitting efficiency of the first Type B light-emitting element GLD1 and the third Type B light-emitting element GLD3 is substantially equal to the light-emitting efficiency of the first Type B repair light-emitting element GRD1 and the second Type B repair light-emitting element GRD2. When the display device 50 displays an image, the maximum brightness of each of the first Type B light-emitting element GLD1, the first Type B repair light-emitting element GRD1, and the second Type B repair light-emitting element GRD2 is reduced through digital compensation.

For example, Table 5 is a digital compensation table for the Type B sub-pixels in FIG. 7D, and the digital compensation value for each Type B sub-pixel in FIG. 7D is shown in the corresponding position in Table 5.

TABLE 5

| | | | |
|---|---|---|---|
| 0.6 | 0.8 | 1 | 1 |
| 1 | 1 | 1 | 1 |

Referring to Table 5 and FIG. 7D, the digital compensation value (for example, 0.6) of the first Type B sub-pixel GSP1′ is lower than the digital compensation value (for example, 0.8) of the second Type B sub-pixel GSP2′, while the digital compensation value of the second Type B sub-pixel GSP2′ is lower than the digital compensation values (for example, 1) of other Type B sub-pixels GSP′ (including the third Type B sub-pixel GSP3′). The larger the digital compensation value, the higher the maximum brightness of the corresponding light-emitting element when the display device 50 displays an image. Reducing the digital compensation value of the first Type B sub-pixel GSP1′ can prevent a bright spot from being formed in the first Type B sub-pixel GSP1′. Reducing the digital compensation value of the second Type B sub-pixel GSP2′ can prevent a bright spot from being formed between the second Type B sub-pixel GSP2′ and the third Type B sub-pixel GSP3′.

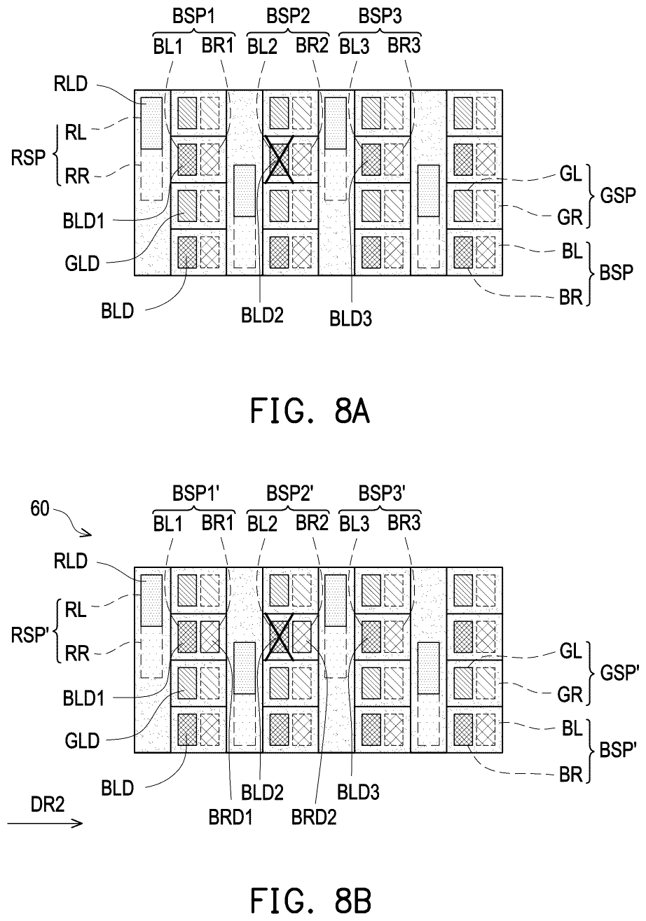

FIG. 8A to FIG. 8B are top views illustrating a manufacturing method of a display device 60 according to an embodiment of the disclosure. It should be noted that the embodiment of FIG. 8A to FIG. 8B uses the reference numerals and some contents from the embodiment of FIG. 7A to FIG. 7D, wherein identical or similar reference numerals are used to represent identical or similar elements, and description of identical technical content is omitted. Please refer to the above embodiment for the omitted content, which will not be repeated here.

FIG. 7A to FIG. 7D illustrate the repair process for Type B light-emitting elements. FIG. 8A and FIG. 8B illustrate the repair process for Type C light-emitting elements. To facilitate the explanation of the repair process for the Type C sub-pixel areas BSP, three of the Type C sub-pixel areas BSP are marked as a first Type C sub-pixel area BSP1, a second Type C sub-pixel area BSP2, and a third Type C sub-pixel area BSP3, and three of the Type C light-emitting elements BLD are marked as a first Type C light-emitting element BLD1, a second Type C light-emitting element BLD2, and a third Type C light-emitting element BLD3. The first Type C sub-pixel area BSP1 has a first Type C default light-emitting area BL1 and a first Type C repair area BR1, the second Type C sub-pixel area BSP2 has a second Type C default light-emitting area BL2 and a second Type C repair area BR2, and the third Type C sub-pixel area BSP3 has a third Type C default light-emitting area BL3 and a third Type C repair area BR3.

FIG. 8A follows the step of FIG. 7B. Referring to FIG. 8A, a test procedure is performed on the Type C light-emitting elements BLD. Through the test procedure, it is determined that the second Type C light-emitting element BLD2 is a malfunctioning light-emitting element, while other Type C light-emitting elements BLD (including the first Type C light-emitting element BLD1 and the third Type C light-emitting element BLD3) emit light during the test procedure (for example, these light-emitting elements normally emit light at expected wavelength and expected brightness).

In FIG. 8A, the malfunctioning light-emitting element is marked with a cross. Although in FIG. 8A to FIG. 8B, the malfunctioning second Type C light-emitting element BLD2 is placed on the second Type C default light-emitting area BL2, the disclosure is not limited thereto. In practice, due to misalignment in the transfer process, there may be no light-emitting element (that is, light-emitting diode) in the second Type C default light-emitting area BL2.

Referring to FIG. 8B, the first Type C repair light-emitting element BRD1 and the second Type C repair light-emitting element BRD2 are transferred onto the first Type C repair area BR1 and the second Type C repair area BR2, respectively, thereby completing the repair of the Type C light-emitting elements.

In this embodiment, the display device 60 includes multiple Type A sub-pixels RSP′, multiple Type B sub-pixels GSP′, and multiple Type C sub-pixels BSP′ (including a first Type C sub-pixel BSP1′, a second Type C sub-pixel BSP2′, and a third Type C sub-pixel BSP3′).

The first Type C sub-pixel BSP1′ has a first Type C default light-emitting area BL1 and a first Type C repair area BR1, and includes a first Type C light-emitting element BLD1 and a first Type C repair light-emitting element BRD1 disposed in the first Type C default light-emitting area BL1 and the first Type C repair area BR1, respectively. The first Type C light-emitting element BLD1 and the first Type C repair light-emitting element BRD1 are connected in parallel. Specifically, the anode of the first Type C light-emitting element BLD1 is electrically connected to the anode of the first Type C repair light-emitting element BRD1, and the cathode of the first Type C light-emitting element BLD1 is electrically connected to the cathode of the first Type C repair light-emitting element BRD1. Therefore, the first Type C light-emitting element BLD1 and the first Type C repair light-emitting element BRD1 turn on and turn off simultaneously.

The second Type C sub-pixel BSP2′ has a second Type C default light-emitting area BL2 and a second Type C repair area BR2, and includes a second Type C repair light-emitting element BRD2 disposed in the second Type C repair area BR2. The second Type C default light-emitting area BL2 does not have any light-emitting diode disposed therein or has the malfunctioning second Type C light-emitting element BLD2.

In this embodiment, to prevent the excessive distance between the second Type C repair light-emitting element BRD2 and the first Type C light-emitting element BLD1 from forming a dark spot, the first Type C repair light-emitting element BRD1 is still disposed in the first Type C repair area BR1 despite that the first Type C light-emitting element BLD1 may operate normally. The distance between the second Type C repair light-emitting element BRD2 adjacent to the first Type C sub-pixel BSP1′ and the first Type C repair light-emitting element BRD1 of the first Type C sub-pixel BSP1′ is substantially equal to the length w of the pixel in the second direction DR2.

The third Type C sub-pixel BSP3′ has a third Type C default light-emitting area BL3 and a third Type C repair area BR3. The third Type C sub-pixel BSP3′ includes a third Type C light-emitting element BLD3 disposed in the third Type C default light-emitting area BL3. The third Type C repair area BR3 does not have any light-emitting diode disposed therein.

The second Type C sub-pixel BSP2′ is located between the first Type C sub-pixel BSP1′ and the third Type C sub-pixel BSP3′ in the second direction DR2. In this embodiment, one second Type C sub-pixel BSP2′ is located between the first Type C sub-pixel BSP1′ and the third Type C sub-pixel BSP3′, but the disclosure is not limited thereto. In other embodiments, two or more second Type C sub-pixels BSP2′ may be located between the first Type C sub-pixel BSP1′ and the third Type C sub-pixel BSP3′.

The first Type C default light-emitting area BL1, the first Type C repair area BR1, the second Type C default light-emitting area BL2, the second Type C repair area BR2, the third Type C default light-emitting area BL3, and the third Type C repair area BR3 are arranged along the second direction DR2, for example, aligned in a row along the second direction DR2.

The first Type C light-emitting element BLD1, the first Type C repair light-emitting element BRD1, the second Type C repair light-emitting element BRD2, and the third Type C light-emitting element BLD3 are light-emitting elements of the same color.

The first Type C light-emitting element BLD1 and the third Type C light-emitting element BLD3 have substantially the same light-emitting efficiency. In some embodiments, the light-emitting efficiency of the first Type C repair light-emitting element BRD1 and the light-emitting efficiency of the second Type C repair light-emitting element BRD2 are the same as or different from the light-emitting efficiency of the first Type C light-emitting element BLD1 and the third Type C light-emitting element BLD3. For example, the light-emitting efficiency of the first Type C repair light-emitting element BRD1 is lower than the light-emitting efficiency of the first Type C light-emitting element BLD1, so that the brightness of the light emitted by the first Type C repair light-emitting element BRD1 is lower than the brightness of the light emitted by the first Type C light-emitting element BLD1. In some embodiments, the light-emitting efficiency of the second Type C repair light-emitting element BRD2 is also lower than the light-emitting efficiency of the first Type C light-emitting element BLD1. In some embodiments, the light-emitting efficiency of the first Type C repair light-emitting element BRD1 is lower than or equal to the light-emitting efficiency of the second Type C repair light-emitting element BRD2. In some embodiments, in addition to using repair light-emitting elements with lower light-emitting efficiency, the quality of the displayed image may be further improved through digital compensation. By using repair light-emitting elements with lower light-emitting efficiency, the magnitude of digital compensation may be relatively small.

In some embodiments, disposing the first Type C repair light-emitting element BRD1 with lower light-emitting efficiency in the first Type C sub-pixel BSP1′ can prevent a bright spot from being formed in the first Type C sub-pixel BSP1′. On the other hand, disposing the second Type C repair light-emitting element BRD2 with lower light-emitting efficiency in the second Type C sub-pixel BSP2′ can prevent a bright spot from being formed between the second Type C sub-pixel BSP2′ and the third Type C sub-pixel BSP3′.

In some embodiments, the light-emitting efficiency of the first Type C light-emitting element BLD1 and the third Type C light-emitting element BLD3 is substantially equal to the light-emitting efficiency of the first Type C repair light-emitting element BRD1 and the second Type C repair light-emitting element BRD2. When the display device 60 displays an image, the maximum brightness of each of the first Type C light-emitting element BLD1, the first Type C repair light-emitting element BRD1, and the second Type C repair light-emitting element BRD2 is reduced through digital compensation.

For example, Table 6 is a digital compensation table for the Type C sub-pixels in FIG. 8B, and the digital compensation value for each Type C sub-pixel in FIG. 8B is shown in the corresponding position in Table 6.

TABLE 6

| | | | |
|---|---|---|---|
| 0.6 | 0.8 | 1 | 1 |
| 1 | 1 | 1 | 1 |

Referring to Table 6 and FIG. 8B, the digital compensation value (for example, 0.6) of the first Type C sub-pixel BSP1′ is lower than the digital compensation value (for example, 0.8) of the second Type C sub-pixel BSP2′, while the digital compensation value of the second Type C sub-pixel BSP2′ is lower than the digital compensation value (for example, 1) of other Type C sub-pixels BSP′ (including the third Type C sub-pixel BSP3′). The larger the digital compensation value, the higher the maximum brightness of the corresponding light-emitting element when the display device 60 displays an image. Reducing the digital compensation value of the first Type C sub-pixel BSP1′ can prevent a bright spot from being formed in the first Type C sub-pixel BSP1′. Reducing the digital compensation value of the second Type C sub-pixel BSP2′ can prevent a bright spot from being formed between the second Type C sub-pixel BSP2′ and the third Type C sub-pixel BSP3′.

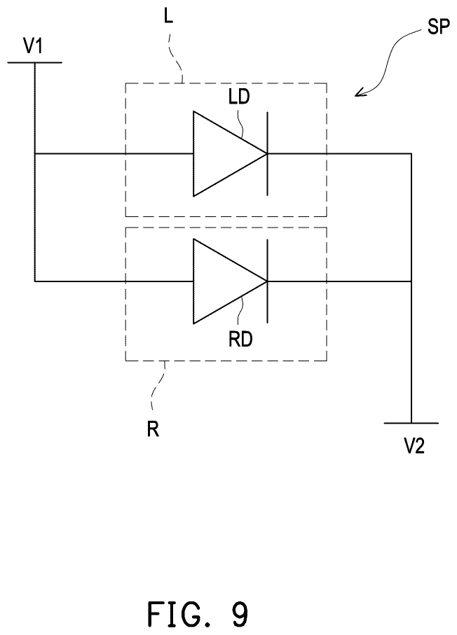

FIG. 9 is a circuit diagram of a sub-pixel SP according to an embodiment of the disclosure. The sub-pixel SP includes a light-emitting element LD and a repair light-emitting element RD. The light-emitting element LD and the repair light-emitting element RD are disposed in a default light-emitting area L and a repair area R, respectively. The anode of the light-emitting element LD and the anode of the repair light-emitting element RD are electrically connected together, for example, connected to a first voltage signal V1. The cathode of the light-emitting element LD and the cathode of the repair light-emitting element RD are electrically connected together, for example, connected to a second voltage signal V2. One of the first voltage signal V1 and the second voltage signal V2 is connected to a sub-pixel driving circuit, and the other is connected as a common voltage signal.

What is claimed is:

1. A display device, comprising:
a first sub-pixel having a first default light-emitting area and a first repair area, and comprising:
a first light-emitting element disposed in the first default light-emitting area, and
a first repair light-emitting element disposed in the first repair area, wherein the first light-emitting element and the first repair light-emitting element are connected in parallel;
at least one second sub-pixel having a second default light-emitting area and a second repair area, wherein the at least one second sub-pixel comprises:
a second repair light-emitting element disposed in the second repair area, wherein the second default light-emitting area does not have any light-emitting diode disposed therein or has a malfunctioning second light-emitting element; and
a third sub-pixel having a third default light-emitting area and a third repair area, wherein the at least one second sub-pixel is located between the first sub-pixel and the third sub-pixel in a first direction, and the third sub-pixel comprises:
a third light-emitting element disposed in the third default light-emitting area, wherein the third repair area does not have any light-emitting diode disposed therein, wherein the first light-emitting element, the first repair light-emitting element, the second repair light-emitting element, and the third light-emitting element are light-emitting elements of the same color, wherein the first default light-emitting area, the first repair area, the second default light-emitting area, the second repair area, the third default light-emitting area, and the third repair area are arranged along the first direction.

2. The display device according to claim 1, wherein a distance between the second repair light-emitting element adjacent to the first sub-pixel and the first repair light-emitting element of the first sub-pixel is substantially equal to a length of the first sub-pixel in the first direction.

3. The display device according to claim 1, further comprising:
a fourth sub-pixel, wherein the fourth sub-pixel has a fourth default light-emitting area and a fourth repair area, and comprises:
a fourth light-emitting element disposed in the fourth default light-emitting area, wherein the fourth light-emitting element and the first light-emitting element are light-emitting elements of the same color, and the fourth light-emitting element and the first light-emitting element are arranged in a staggered manner in a second direction perpendicular to the first direction.

4. The display device according to claim 1, wherein light-emitting efficiency of the first repair light-emitting element and light-emitting efficiency of the second repair light-emitting element are lower than light-emitting efficiency of the first light-emitting element.

5. The display device according to claim 1, wherein the first sub-pixel, the at least one second sub-pixel, and the third sub-pixel are red sub-pixels, and the display device further comprises:
a first green sub-pixel having a first green default light-emitting area and a first green repair area, and comprising:
a first green light-emitting element disposed in the first green default light-emitting area, and
a first green repair light-emitting element disposed in the first green repair area, wherein the first green light-emitting element and the first green repair light-emitting element are connected in parallel;
at least one second green sub-pixel having a second green default light-emitting area and a second green repair area, wherein the at least one second green sub-pixel comprises:
a second green repair light-emitting element disposed in the second green repair area, wherein the second green default light-emitting area does not have any light-emitting diode disposed therein or has a malfunctioning second green light-emitting element; and
a third green sub-pixel having a third green default light-emitting area and a third green repair area, wherein the at least one second green sub-pixel is located between the first green sub-pixel and the third green sub-pixel in a second direction, and the third green sub-pixel comprises:
a third green light-emitting element disposed in the third green default light-emitting area, wherein the third green repair area does not have any light-emitting diode disposed therein, wherein the first green default light-emitting area, the first green repair area, the second green default light-emitting area, the second green repair area, the third green default light-emitting area, and the third green repair area are arranged along the second direction, wherein the second direction is not parallel to the first direction.

6. The display device according to claim 5, further comprising:
a first blue sub-pixel having a first blue default light-emitting area and a first blue repair area, and comprising:
a first blue light-emitting element disposed in the first blue default light-emitting area, and
a first blue repair light-emitting element disposed in the first blue repair area, wherein the first blue light-emitting element and the first blue repair light-emitting element are connected in parallel;
at least one second blue sub-pixel having a second blue default light-emitting area and a second blue repair area, wherein the at least one second blue sub-pixel comprises:
a second blue repair light-emitting element disposed in the second blue repair area, wherein the second blue default light-emitting area does not have any light-emitting diode disposed therein or has a malfunctioning second blue light-emitting element; and
a third blue sub-pixel having a third blue default light-emitting area and a third blue repair area, wherein the at least one second blue sub-pixel is located between the first blue sub-pixel and the third blue sub-pixel in a second direction, and the third blue sub-pixel comprises:
a third blue light-emitting element disposed in the third blue default light-emitting area, wherein the third blue repair area does not have any light-emitting diode disposed therein, wherein the first blue default light-emitting area, the first blue repair area, the second blue default light-emitting area, the second blue repair area, the third blue default light-emitting area, and the third blue repair area are arranged along the second direction.

7. The display device according to claim 1, wherein the number of the at least one second sub-pixel is two or more.

8. A repair method of a display device, comprising:
providing a circuit substrate, the circuit substrate comprising:
a first sub-pixel area having a first default light-emitting area and a first repair area,
a second sub-pixel area having a second default light-emitting area and a second repair area, and
a third sub-pixel area having a third default light-emitting area and a third repair area;
transferring a first light-emitting element, a second light-emitting element, and a third light-emitting element to the first default light-emitting area, the second default light-emitting area, and the third default light-emitting area, respectively;
performing a test procedure on the first light-emitting element, the second light-emitting element, and the third light-emitting element, wherein the second light-emitting element is malfunctioning, while the first light-emitting element and the third light-emitting element emit light during the test procedure; and
transferring a first repair light-emitting element and a second repair light-emitting element to the first repair area and the second repair area, respectively.

9. The repair method according to claim 8, further comprising:
reducing a maximum brightness of each of the first light-emitting element, the first repair light-emitting element, and the second repair light-emitting element when the display device displays an image through digital compensation.

10. The repair method according to claim 8, wherein light-emitting efficiency of the first repair light-emitting element and light-emitting efficiency of the second repair light-emitting element are lower than light-emitting efficiency of the first light-emitting element.
